(19) United States
(12) Patent Application Publication
(10) Pub. No.: US 2025/0311542 A1
(43) Pub. Date: Oct. 2, 2025

(54) DISPLAY PANEL AND CONTROL CIRCUIT

(71) Applicant: HKC CORPORATION LIMITED, SHENZHEN (CN)

(72) Inventors: Yunzhuo LIU, SHENZHEN (CN); Hao FU, SHENZHEN (CN); Qiang SHUANG, SHENZHEN (CN); Qiang HOU, SHENZHEN (CN); Lulin MA, SHENZHEN (CN); Qiuping MO, SHENZHEN (CN); Lidan YE, SHENZHEN (CN)

(73) Assignee: HKC CORPORATION LIMITED, SHENZHEN (CN)

(21) Appl. No.: 19/066,793

(22) Filed: Feb. 28, 2025

(30) Foreign Application Priority Data
Mar. 27, 2024 (CN) 202410355227.1

(51) Int. Cl. H10K 50/80; H10K 102/00

(52) U.S. Cl. CPC H10K 50/80; H10K 2102/311; H10K 2102/331

(57) ABSTRACT

A display panel includes a driving substrate and a plurality of sub-pixels arranged on the driving substrate. The sub-pixels include a first sub-pixel, a second sub-pixel, and a third sub-pixel with different colors. At least one first sub-pixel includes a first magnetic layer arranged between an anode and a hole transport layer or between a cathode and an electron transport layer. The first magnetic layer includes a plurality of magnetic particles. The first sub-pixel also includes a first magnetic-field applying assembly, including a first magnetic member and a second magnetic member respectively arranged at two opposite ends of the first magnetic layer along a first direction. At least one of the first magnetic member and the second magnetic member includes an electromagnet. The first magnetic-field applying assembly is configured to control distribution of the magnetic particles in the first magnetic layer. A control circuit is further provided.

### CROSS REFERENCE TO RELATED APPLICATIONS

The present disclosure claims priority to Chinese patent application No. 202410355227.1 filed on Mar. 27, 2024, the entire contents of which are incorporated herein by reference.

### TECHNICAL FIELD

The present disclosure relates to the field of display technologies, and in particular to a display panel and a control circuit.

### BACKGROUND

Organic light-emitting diode (OLED) is a light-emitting device that uses organic solid-state semiconductors as light-emitting materials, which has a broad application prospect due to its advantages such as simple production process, low cost, low power consumption, high luminous brightness, and wide operating temperature range.

Each pixel of an OLED display panel is composed of one of three organic light-emitting materials of red, green, and blue. Lifespans of these materials are different. Generally speaking, the organic light-emitting material of blue has the shortest lifespan and the organic light-emitting material of red has the longest lifespan. In addition, luminous efficiency of blue organic material is low, so a larger current is required to applied to display a same effect. Therefore, in response to displaying a same image or text for a long time, a blue diode may decay or be damaged faster than diodes of other colors, resulting in chromatic aberration or afterimage on a screen of the OLED display panel.

In addition, the brightness and contrast of the OLED display panel are very high, which indicates that a larger current is required to drive the OLED display panel. In response to being used or charged for a long time, excessive current may accelerate the aging or damage of the pixel, resulting in bright or dark spots on the screen.

### SUMMARY OF THE DISCLOSURE

In order to solve the above technical problems, a technical solution provided by the present disclosure is a display panel, including a driving substrate and a plurality of sub-pixels. The plurality of sub-pixels is arranged on the driving substrate, the sub-pixels include a first sub-pixel, a second sub-pixel, and a third sub-pixel with different colors, and each of the sub-pixels includes an anode, a hole transport layer, a light-emitting layer, an electron transport layer, and a cathode, which are arranged in a stack on a side of the driving substrate. At least one first sub-pixel includes a first magnetic layer and a first magnetic-field applying assembly. The first magnetic layer is arranged between the anode and the hole transport layer or between the cathode and the electron transport layer of the first magnetic layer, and the first magnetic layer includes a plurality of magnetic particles. The first magnetic-field applying assembly includes a first magnetic member and a second magnetic member respectively arranged at two opposite ends of the first magnetic layer along a first direction, at least one of the first magnetic member and the second magnetic member includes an electromagnet, the first magnetic-field applying assembly is configured to control distribution of the magnetic particles in the first magnetic layer, and the first direction is perpendicular to a stacking direction of the display panel.

In order to solve the above technical problem, another technical solution provided by the present disclosure is a control circuit configured to control a display panel. The display panel includes a plurality of sub-pixels, and at least one of the plurality of sub-pixels includes an anode, a hole transport layer, a light-emitting layer, an electron transport layer, a cathode, a magnetic layer, and a magnetic-field applying assembly. The magnetic layer is arranged between the anode and the hole transport layer or between the cathode and the electron transport layer, and the magnetic layer includes a plurality of magnetic particles. The magnetic-field applying assembly includes a first magnetic member and a second magnetic member respectively arranged at two opposite ends of the magnetic layer along a first direction, at least one of the first magnetic member and the second magnetic member includes an electromagnet, the magnetic-field applying assembly is configured to control distribution of the magnetic particles in the magnetic layer, and the first direction is perpendicular to a stacking direction of the display panel. The control circuit includes a display driving unit and a control unit. The display driving unit is configured to drive the sub-pixels of the display panel to display an image. The control unit is electrically connected to the display driving unit and configured to obtain a continuous luminous duration of each of the sub-pixels of the display panel, the control unit is further electrically connected to the magnetic-field applying assembly of the each of the sub-pixels, and configured to control magnetic field strength of the magnetic-field applying assembly based on the continuous luminous duration of the each of the sub-pixels, so as to adjust the distribution of the magnetic particles in the magnetic layer of the display panel.

In order to solve the above technical problem, further another technical solution provided by the present disclosure is a control circuit configured to control a display panel. The display panel includes a plurality of sub-pixels, the plurality of sub-pixels form a plurality of pixel islands arranged in an array, each of two adjacent pixel islands is connected by a flexible connecting wire and a force sensor, and at least one of the plurality of sub-pixels includes an anode, a hole transport layer, a light-emitting layer, an electron transport layer, a cathode, a magnetic layer, and a magnetic-field applying assembly. The magnetic layer is arranged between the anode and the hole transport layer or between the cathode and the electron transport layer, and the magnetic layer includes a plurality of magnetic particles. The magnetic-field applying assembly includes a first magnetic member and a second magnetic member respectively arranged at two opposite ends of the magnetic layer along a first direction, at least one of the first magnetic member and the second magnetic member includes an electromagnet, the magnetic-field applying assembly is configured to control distribution of the magnetic particles in the magnetic layer, and the first direction is perpendicular to a stacking direction of the display panel. The control circuit includes a display driving unit and a control unit. The display driving unit is configured to drive the sub-pixels of the display panel. The control unit is electrically connected to the force sensor and configured to obtain a tensile length or tensile strength tested by the force sensor, and further electrically connected to the magnetic-field applying assembly and configured to control magnetic field strength of the magnetic-field applying assembly based on the tensile strength or tensile strength tested by the force sensor, so as to adjust the distribution of the magnetic particles in the magnetic layer.

### BRIEF DESCRIPTION OF THE DRAWINGS

FIG. 1a is a schematic structural view of a display panel based on a first embodiment of the present disclosure.

FIG. 1b is a schematic structural view of a second sub-pixel based on an embodiment of the present disclosure.

FIG. 1c is a schematic structural view of a third sub-pixel based on an embodiment of the present disclosure.

FIG. 2a is a schematic structural view of a first magnetic layer of the display panel shown in FIG. 1a based on an embodiment of the present disclosure.

FIG. 2b is a schematic structural view of magnetic particles after diffusing in the first magnetic layer shown in FIG. 2a based on an embodiment of the present disclosure.

FIG. 2c is a schematic cross-sectional view of the first magnetic layer shown in FIG. 2a along line A-A based on an embodiment of the present disclosure.

FIG. 3 is a schematic view of a control circuit based on an embodiment of the present disclosure.

FIG. 4 is a schematic structural view of a display panel based on a second embodiment of the present disclosure.

FIG. 5 is a schematic view of a control circuit based on another embodiment of the present disclosure.

### DETAILED DESCRIPTION

The technical solutions in the embodiments of the present disclosure are clearly and thoroughly described below in conjunction with the drawings in the embodiments of the present disclosure. Obviously, the embodiments described are merely a part of the embodiments, rather than all the embodiments, of the present disclosure. Based on the embodiments of the present disclosure, all other embodiments obtained by a person of ordinary skills in the art without creative work fall within the scope of protection of the present disclosure.

The terms “first”, “second”, and “third” in the present disclosure are used for descriptive purposes only and may not be understood to indicate or imply relative importance or implicitly specify the number of technical features indicated. Thus, a feature defined with the terms “first”, “second”, and “third” may, either explicitly or implicitly, include that at least one such feature is provided. In the description of the present disclosure, “plurality” means at least two, e.g., two, three, and etc., unless otherwise explicitly and specifically indicated. All directional indications (e.g., top, bottom, left, right, front, and back . . . ) in the embodiments of the present disclosure are only used to explain the relative relationship, movement, and etc. between the components in a particular positioning (as shown in the drawings), and the directional indications may be changed accordingly given the positioning being changed. In addition, the terms “including”, “having”, and any variations thereof are intended to indicate a non-exclusive inclusion. For example, a process, method, system, product or device including a series of steps or units is not limited to the listed steps or units, but optionally may further include steps or units that are not listed, or other steps or units that are inherent to the process, method, product, or device.

References to “embodiment” in the specification of the present disclosure indicate that a particular feature, structure, or characteristic described in conjunction with the embodiment may be provided in one or more embodiments of the present disclosure. The “embodiment” appeared across the specification refers to neither necessarily the identical embodiment, nor a separate or alternate embodiment that is mutually exclusive with other embodiments. It can be understood by the person of ordinary skills in the art, both explicitly and implicitly, that the embodiments described herein may be combined with other embodiments.

In conjunction with the drawings, the implementations based on the embodiments of the present disclosure are described in details as follows.

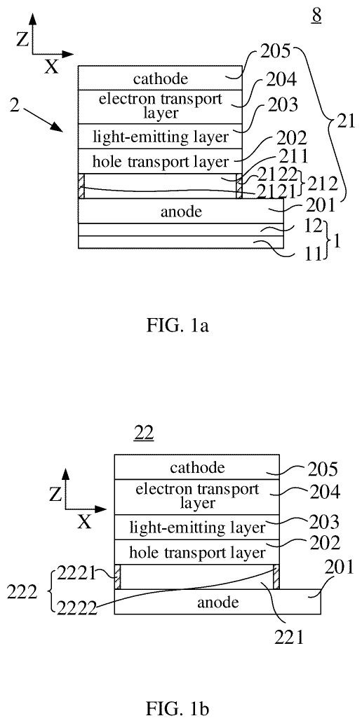

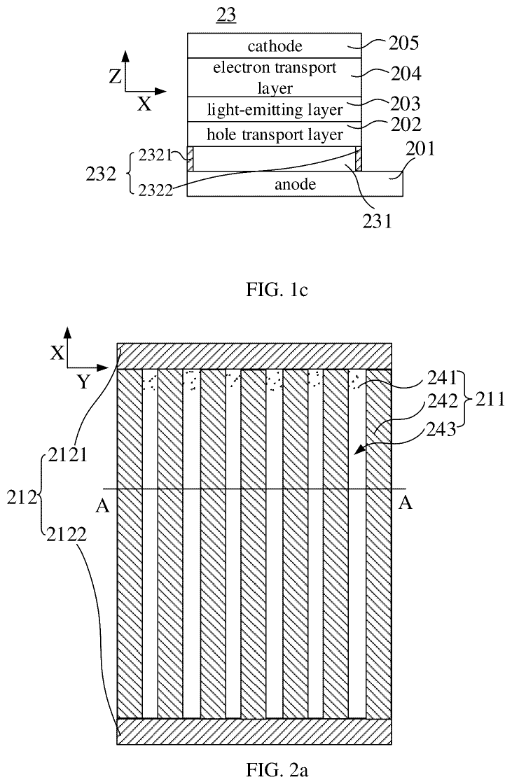

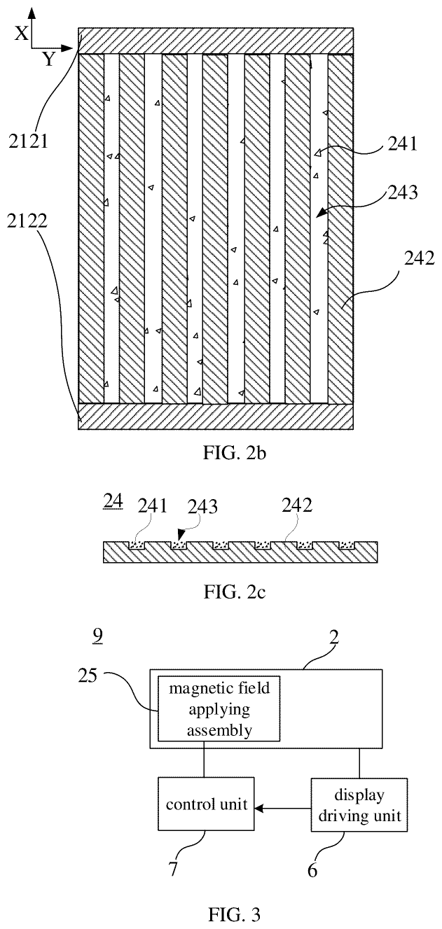

As shown in FIG. 1a to FIG. 2c, FIG. 1a is a schematic structural view of a display panel based on a first embodiment of the present disclosure; FIG. 1b is a schematic structural view of a second sub-pixel based on an embodiment of the present disclosure; FIG. 1c is a schematic structural view of a third sub-pixel based on an embodiment of the present disclosure; FIG. 2a is a schematic structural view of a first magnetic layer of the display panel shown in FIG. 1a based on an embodiment of the present disclosure; FIG. 2b is a schematic structural view of magnetic particles after diffusing in the first magnetic layer shown in FIG. 2a based on an embodiment of the present disclosure; FIG. 2c is a schematic cross-sectional view of the first magnetic layer shown in FIG. 2a along line A-A based on an embodiment of the present disclosure. The present disclosure provides a display panel 8, which may be an active matrix organic light-emitting diode (AMOLED) display panel. The display panel 8 includes a driving substrate 1 and a plurality of sub-pixels 2 arranged on the driving substrate 1. The driving substrate 1 is configured to electrically connected to the sub-pixels 2 and drive the sub-pixels 2 to emit lights.

In some embodiments, the sub-pixels 2 may include a first sub-pixel 21 (as shown in FIG. 1a), a second sub-pixel 22 (as shown in FIG. 1b), and a third sub-pixel 23 (as shown in FIG. 1c) with different colors. Each of the sub-pixels 2 includes an anode 201, a hole transport layer 202, a light-emitting layer 203, an electron transport layer 204, and a cathode 205, which are arranged in a stack on a side of the driving substrate 1. The anode 201 is connected to an anode power wire, and the cathode 205 is connected to a cathode power wire. When voltages are applied to both the cathode 205 and the anode 201 through the driving substrate 1, electrons are injected into the electron transport layer 204 from the cathode 205, holes are injected into the hole transport layer 202 from the anode 201, and both the electrons and the holes are further injected into the light-emitting layer and recombine to form excitons in the light-emitting layer. The excitons are emitted in the form of photons after radiation decay, such that the sub-pixels 2 are enabled to emit lights.

For ease of understanding, effects of magnetic particles on a recombination rate of holes and electrons are described in details as follows. In related art, motion of the holes and electrons in a magnetic field may be deflected by an action of the magnetic field, thereby affecting mobility of the holes and electrons. Majority carriers of a P-type organic light-emitting diode (OLED) are holes, and majority carriers of a N-type OLED are electrons. However, too much holes or electrons may cause exciton quenching, thereby reducing photons. Taking the majority carriers are holes as an example, the magnetic particles arranged between the anode 201 and the hole transport layer 202 may obstruct transmission of the holes, thereby reducing effects of holes on exciton quenching, and improving luminous efficiency. However, as the number of the magnetic particles increases or a diffusion area of the magnetic particles increases, the obstruction of the magnetic particles increases. In this case, the number of the holes migrating to the light-emitting layer may decrease, and the recombination rate of the holes and electrons may decrease. The decrease of the recombination rate may to some extent decrease a decay rate of the OLED (i.e., the P-type OLED or the N-type OLED), because recombination process of the holes and electrons may cause damage to material of the OLED. Magnetic particles provided by the present disclosure are configured to regulate a mobility of the majority carriers, thereby weighing the service life and luminous efficiency of the OLED in different application scenarios.

As shown in FIG. 1a, at least one first sub-pixel 21 includes a first magnetic layer 211 and a first magnetic-field applying assembly 212. The first magnetic layer 211 may include a plurality of magnetic particles 241. The first magnetic layer 211 may be disposed between the anode 201 and the hole transport layer 202 to reduce a mobility of holes. The first magnetic layer 211 may be disposed between the cathode 205 and the electron transport layer 204 to reduce a mobility of electrons. A location of magnetic layer in the embodiments of the present disclosure may be decided based on type of the majority carriers. For example, when the majority carriers are holes, the magnetic layer may be disposed between the anode 201 and the hole transport layer 202; and when the majority carriers are electrons, the magnetic layer may be disposed between the cathode 205 and the electron transport layer 204.

The first magnetic-field applying assembly 212 includes a first magnetic member 2121 and a second magnetic member 2122 respectively arranged at two opposite ends of the first magnetic layer 211 along a first direction X. At least one of the first magnetic member 2121 and the second magnetic member 2122 includes an electromagnet. The first magnetic-field applying assembly 212 is configured to control distribution of the magnetic particles 241 in the first magnetic layer 211. The first direction X is perpendicular to a stacking direction Z of the display panel 8. The first magnetic-field applying assembly 212 is arranged to control the distribution of the magnetic particles 241 in the first magnetic layer 211, such that the magnetic particles 241 are enabled to diffuse in the first magnetic layer 211 after the first sub-pixel 21 continuously emits light for a long time. In this way, the mobility of the majority carriers (i.e., electrons or holes) on a side of the light-emitting layer toward the first magnetic layer 211 may greatly be reduced, and the number of photons generated by recombination of electrons and holes may be reduced, thereby reducing the luminous brightness of the first sub-pixel 21, avoiding damage of the first sub-pixel 21 caused by working at a same brightness for a long time and accelerating aging, and effectively extending the service life of the display panel 8. Besides, the first magnetic-field applying assembly 212 may enable the magnetic particles 241 to gather at an end of the first magnetic layer 211 when the first sub-pixel continues to emit light, so as to prevent the magnetic particles 241 from affecting the normal light emission of the first sub-pixel.

In some embodiments, the first magnetic-field applying assembly 212 is configured to be able to gather the plurality of magnetic particles 241 at the end of the first magnetic layer 211. The first magnetic-field applying assembly 212 is also configured to be able to drive the plurality of magnetic particles 241 to move toward the other end of the first magnetic layer 211. When strength of a magnetic field applied to the first magnetic layer 211 increases, the number of moving magnetic particles 241 increases.

In some embodiments, one of the first magnetic member 2121 and the second magnetic member 2122 may include a permanent magnet, and the other one of the first magnetic member 2121 and the second magnetic member 2122 may include the electromagnet. As shown in FIG. 2a, in some embodiments, the first magnetic member 2121 includes the permanent magnet, and the second magnetic member 2122 includes the electromagnet. In some embodiments, when the second magnetic member 2122 is not energized, the magnetic particles 241 in the first magnetic layer 211 are adsorbed by the first magnetic member 2121. The magnetic particles 241 gather at an end of the first magnetic layer 211 close to the first magnetic member 2121 along the first direction X, such that the carriers are enabled to pass through the first magnetic layer 211 with normal mobility, and the first sub-pixel 21 may emit light normally. As shown in FIG. 2b, when the second magnetic member 2122 is energized, the magnetic field strength between the first magnetic member 2121 and the second magnetic member 2122 changes. The second magnetic member 2122 attracts the plurality of magnetic particles 241 to diffuse from the end of the first magnetic layer 211 close to the first magnetic member 2121 along a direction close to the second magnetic member 2122, thereby greatly reducing the mobility of the carriers, so as to weakened the light emission intensity of the first sub-pixel 21.

In some embodiments, the thickness of the magnetic particles 241 in the first magnetic layer 211 along the stacking direction Z may be controlled by controlling the magnitude of an energized voltage applied to the second magnetic member 2122, thereby controlling the mobility of the carriers.

In some embodiments, the first magnetic member 2121 and the second magnetic member 2122 may both include the electromagnet. The magnetic field between the first magnetic member 2121 and the second magnetic member 2122 may be controlled by controlling the magnitude of an energized voltage applied to the first magnetic member 2121 and the magnitude of the energized voltage applied to the second magnetic member 2122, thereby controlling the distribution of the magnetic particles 241 in the first magnetic layer 211. The following embodiments of the present disclosure are described by taking the first magnetic member 2121 includes the permanent magnet and the second magnetic member 2122 includes the electromagnet as an example.

As shown in FIG. 2a and FIG. 2c, in some embodiments, the first magnetic layer 211 is defined with a plurality of accommodating grooves 243 extending in the first direction X. The plurality of accommodating grooves 243 are arranged at intervals along a second direction Y. The magnetic particles 241 are disposed in the accommodating grooves 243 and are able to move along the accommodating grooves 243 under an action of the magnetic field. The second direction Y is perpendicular to both the stacking direction Z of the display panel 8 and the first direction X. In some embodiments, the first magnetic layer 211 further includes a base 242 configured to provide support for the first magnetic layer 211. A portion of a surface of the base 242 away from the anode 201 is in contact with the hole transport layer 202, and another portion of the surface of the base 242 away from the anode 201 is recessed to form the accommodating grooves 243. In some embodiments, the base 242 may be one of a conductive material, nitrogen-phosphorus-boron (as a material of the hole transport layer 202), or indium-aluminum-arsenic (as a material of the electron transport layer 204).

In some embodiments, the magnetic particles 241 are able to move along the first direction X under an attraction of the first magnetic member 2121 or the second magnetic member 2122. The magnetic particles 241 may be one or more of iron powder or magnetic powder. For example, the magnetic particles 241 may be one of iron powder, magnetic iron oxide powder, chromium dioxide magnetic powder, or cobalt-iron oxide magnetic powder. The magnetic particles 241 may also be a mixture of any two or more of iron powder, magnetic iron oxide powder, chromium dioxide magnetic powder, and cobalt-iron oxide magnetic powder. The magnetic particles 241 are nano-sized powders.

As shown in FIG. 1b, in some embodiments, the second sub-pixel 22 may include a second magnetic layer 221 and a second magnetic-field applying assembly 222. The second magnetic layer 221 may include a plurality of magnetic particles 241. The second magnetic layer 221 may be disposed between the anode 201 and the hole transport layer 202 of the second sub-pixel 22 to reduce the mobility of holes. The second magnetic layer 221 may also be disposed between the cathode 205 and the electron transport layer 204 of the second sub-pixel 22 to reduce the mobility of electrons.

The second magnetic-field applying assembly 222 includes a third magnetic member 2221 and a fourth magnetic member 2222 respectively disposed at two opposite ends of the second magnetic layer 221 along the first direction X. At least one of the third magnetic member 2221 and the fourth magnetic member 2222 includes an electromagnet. The second magnetic-field applying assembly 222 is configured to control distribution of the magnetic particles 241 in the second magnetic layer 221. The structure and function of the second magnetic-field applying assembly 222 are the same as those of the first magnetic-field applying assembly 212 involved in the above embodiments, and details may be referred to the above contents, and will not be repeated herein.

The distribution of the magnetic particles 241 of the second magnetic layer 221 in the second magnetic layer 221 is controlled by arranging the second magnetic-field applying assembly 222 in the second sub-pixel 22, such that the magnetic particles 241 are enabled to diffuse in the second magnetic layer 221 after the second sub-pixel 22 continuously emits light for a long time. In this way, the mobility of the carriers may greatly be reduced, and the luminous brightness of the second sub-pixel 22 may be temporarily reduced, thereby avoiding damage of the second sub-pixel 22 caused by working at a same brightness for a long time and accelerating aging.

As shown in FIG. 1c, in some embodiments, the third sub-pixel 23 may include a third magnetic layer 231 and a third magnetic-field applying assembly 232. The third magnetic layer 231 includes a plurality of magnetic particles 241. The third magnetic layer 231 may be disposed between the anode 201 and the hole transport layer 202 of the third sub-pixel 23 to reduce the mobility of holes. The third magnetic layer 231 may also be disposed between the cathode 205 and the electron transport layer 204 of the third sub-pixel 23 to reduce the mobility of electrons.

The third magnetic-field applying assembly 232 may include a fifth magnetic member 2321 and a sixth magnetic member 2322 respectively disposed at two opposite ends of the third magnetic layer 231 along the first direction X. At least one of the fifth magnetic member 2321 and the sixth magnetic member 2322 includes an electromagnet. The third magnetic-field applying assembly 232 is configured to control distribution of the magnetic particles 241 in the third magnetic layer 231. The structure and function of the third magnetic-field applying assembly 232 are the same as those of the first magnetic-field applying assembly 212 involved in the above embodiments, and details may be referred to the above contents and will not be repeated herein.

The distribution of the magnetic particles 241 of the third magnetic layer 231 in the third magnetic layer 231 is controlled by arranging the third magnetic-field applying assembly 232 in the third sub-pixel 23, such that the magnetic particles 241 are enabled to diffuse in the third magnetic layer 231 after the third sub-pixel 23 continuously emits light for a long time. In this way, the mobility of the carriers may greatly be reduced, and the luminous brightness of the third sub-pixel 23 may be temporarily reduced, thereby avoiding damage of the third sub-pixel 23 caused by working at a same brightness for a long time and accelerating aging.

The color of the first sub-pixel 21 may be blue, the color of the second sub-pixel 22 may be one of red and green, and the color of the third sub-pixel 23 may be the other of red and green. Among three sub-pixels of red, blue and green, a blue sub-pixel decays faster and generally has a shorter service life than the other two sub-pixels. Therefore, in some embodiments, the first magnetic-field applying assembly 212 is arranged in the blue sub-pixel to avoid damage of the blue sub-pixel caused by working at a same brightness for a long time and accelerating aging, thereby delaying the aging speed of the blue sub-pixel and effectively increasing the service life of the blue sub-pixel.

In some embodiments, the second magnetic-field applying assembly may be provided in a red sub-pixel, or the third magnetic-field applying assembly may be provided in a green sub-pixel based on actual demands to increase service life of the red sub-pixel and the green sub-pixel.

In some embodiments, the driving substrate 1 includes a substrate 11 and a driving circuit layer 12 disposed on the substrate 11. The substrate 11 is configured to support and protect various components of the display panel 8. The driving circuit layer 12 may be configured to drive the sub-pixels to emit light. The driving circuit layer 12 may include a plurality of routing wires. A magnetic-field applying assembly corresponding to each of the sub-pixels is connected to the driving circuit layer 12 through a corresponding one of the routing wires. The magnetic-field applying assembly may be any one of the first magnetic-field applying assembly 212, the second magnetic-field applying assembly, and the third magnetic-field applying assembly. The driving circuit layer 12 may apply a voltage to the magnetic-field applying assembly of one of the sub-pixels through the corresponding one of the routing wires to change a magnetic field of the magnetic-field applying assembly, thereby changing the distribution of the magnetic particles 241 in the one of the sub-pixels.

In some embodiments, magnetic field applying assemblies corresponding to multiple adjacent sub-pixels 2 may be arranged to be electrically connected to the driving circuit layer 12 through a same routing wire. The driving circuit layer 12 may apply voltage to multiple adjacent magnetic field applying assemblies through the same routing wire to change the distribution of magnetic particles 241 in multiple adjacent sub-pixels.

The embodiments of the present disclosure provides the display panel 8 including the driving substrate 1 and the plurality of sub-pixels arranged on the driving substrate 1. The sub-pixels include the first sub-pixel 21, the second sub-pixel 22, and the third sub-pixel 23 with different colors. Each of the sub-pixels includes the anode 201, the hole transport layer 202, the light-emitting layer, the electron transport layer 204, and the cathode 205, which are arranged in a stack on the side of the driving substrate 1. At least one first sub-pixel 21 includes the first magnetic layer 211 arranged between the anode 201 and the hole transport layer 202 or between the cathode 205 and the electron transport layer 204. The first magnetic layer 211 includes the plurality of magnetic particles 241. The first sub-pixel 21 also includes the first magnetic-field applying assembly 212. The first magnetic-field applying assembly 212 includes the first magnetic member 2121 and the second magnetic member 2122 respectively arranged at two opposite ends of the first magnetic layer 211 along a first direction. At least one of the first magnetic member 2121 and the second magnetic member 2122 includes the electromagnet. The first magnetic-field applying assembly 212 is configured to control the distribution of the magnetic particles 241 of the first magnetic layer 211 in the first magnetic layer 211. The first magnetic-field applying assembly 212 is arranged to control the distribution of the magnetic particles 241 in the first magnetic layer 211, such that the magnetic particles 241 are enabled to diffuse in the first magnetic layer 211 after the first sub-pixel 21 continuously emits light for a long time. In this way, the mobility of the carriers on the side of the light-emitting layer toward the first magnetic layer 211 may greatly be reduced, and the number of photons generated by recombination of electrons and holes may be reduced, thereby reducing the luminous brightness of the first sub-pixel 21, avoiding damage of the first sub-pixel 21 caused by working at a same brightness for a long time and accelerating aging, and effectively extending the service life of the display panel 8. Besides, the first magnetic-field applying assembly 212 may enable the magnetic particles 241 to gather at the end of the first magnetic layer 211 when the first sub-pixel continues to emit light, so as to avoid affecting the normal light emission of the sub-pixels.

As shown in FIG. 3, FIG. 3 is a schematic view of a control circuit based on an embodiment of the present disclosure. The present disclosure further provides a control circuit 9 configured to control the display panel 8 involved in the embodiments mentioned above. As shown in FIG. 1a and FIG. 2a, the display panel 8 includes the plurality of sub-pixels 2. At least one of the plurality of sub-pixels 2 includes the anode 201, the hole transport layer 202, the light-emitting layer 203, the electron transport layer 204, the cathode 205, the magnetic layer 24 (e.g., the first magnetic layer 211 shown in FIG. 1a, the second magnetic layer 221 shown in FIG. 1b, and the third magnetic layer 231 shown in FIG. 1c), and the magnetic-field applying assembly 25. The magnetic layer 24 is arranged between the anode 201 and the hole transport layer or between the cathode 205 and the electron transport layer 204. The magnetic layer 24 includes the plurality of magnetic particles 241. The magnetic-field applying assembly 25 includes the first magnetic member 2121 and the second magnetic member 2122 respectively arranged at two opposite ends of the magnetic layer 24 along the first direction X. At least one of the first magnetic member 2121 and the second magnetic member 2122 includes the electromagnet. The magnetic-field applying assembly 25 is configured to control the distribution of the magnetic particles 241 of the magnetic layer 24 in the magnetic layer 24.

In some embodiments, the control circuit 9 may include a display driving unit 6 and a control unit 7. The display driving unit 6 is configured to drive the sub-pixels 2 of the display panel 8 to display an image. The control unit 7 is electrically connected to the display driving unit 6, and is configured to obtain a continuous luminous duration of each of the sub-pixels 2 of the display panel 8. The control unit 7 is also electrically connected to the magnetic-field applying assembly 25 of the each of the sub-pixels 2, and is configured to control magnetic field strength of the magnetic-field applying assembly 25 of the each of the sub-pixels 2 based on the continuous luminous duration of the each of the sub-pixels 2, so as to adjust the distribution of magnetic particles 241 in the magnetic layer 24 of the display panel 8.

In this way, the magnetic particles 241 may diffuse in the magnetic layer 24 after the sub-pixels 2 continuously emits light for a long time, thereby greatly reducing the mobility of the carriers on the side of the light-emitting layer 203 toward the magnetic layer 24, reducing the number of photons generated by recombination of electrons and holes, reducing the luminous brightness of the sub-pixels 2, avoiding damage of the sub-pixels 2 caused by working at a same brightness for a long time and accelerating aging, and effectively extending the service life of the display panel 8.

In some embodiments, as shown in FIG. 2a to FIG. 3, the control unit 7 is electrically connected to the second magnetic member 2122, and is used to apply voltage to the second magnetic member 2122. The magnetic field strength of the magnetic-field applying assembly 25 is changed by controlling whether voltage is applied to the second magnetic member 2122 and a magnitude of the voltage applied to the second magnetic member 2122, thereby controlling the distribution of magnetic particles 241 in the magnetic layer 24.

In some embodiments, in response to the continuous luminous duration of one of the sub-pixels 2 being smaller than a first preset duration, the control unit 7 may control a corresponding magnetic-field applying assembly 25 to apply a first magnetic field to the magnetic particles 241, such that the magnetic particles 241 are enabled to be distributed at one end of the magnetic layer 24 along the first direction. It should be noted that the continuous luminous duration of the one of the sub-pixels 2 is a duration during which the one of the sub-pixels 2 maintains a same luminous brightness of a fixed picture or multiple pictures.

In some embodiments, as shown in FIG. 2a and FIG. 3, the control unit 7 may not apply voltage to the second magnetic member 2122. The magnetic particles 241 in the magnetic layer 24 are adsorbed by the first magnetic member 2121 and gathered at an end of the magnetic layer 24 close to the first magnetic member 2121. In this way, the carriers may be injected into the light-emitting layer 203 with normal mobility, and the sub-pixels 2 may emit light normally. When the sub-pixels 2 does not emit light, the control unit 7 may also control the magnetic-field applying assembly 25 to apply the first magnetic field to the magnetic particles 241 to save energy.

In response to the continuous luminous duration of one of the sub-pixels 2 being greater than or substantially equal to the first preset duration, the control unit 7 may control a corresponding magnetic-field applying assembly 25 to apply a second magnetic field to the magnetic particles 241, such that a first preset number of magnetic particles 241 is enabled to diffuse from an end of the magnetic layer 24 to the other end of the magnetic layer 24 along the first direction X and into a first distribution region, so as to reduce the recombination rate of holes and electrons. In some embodiments, the first preset number is relatively large, and the first distribution region is relatively big. For example, an area of the first distribution region may account for more than half of an area of the magnetic layer 24. In this way, when the magnetic-field applying assembly 25 applies the second magnetic field to the magnetic particles 241, a large number of the magnetic particles 241 may greatly reduce the mobility of the majority carriers, thereby affecting combination of the majority carriers and the minority carriers, and reducing luminous efficiency.

In some embodiments, as shown in FIG. 2b and FIG. 3, the control unit 7 applies a first preset voltage to the second magnetic member 2122. The second magnetic member 2122 is energized to generate magnetism, and the second magnetic field is formed between the first magnetic member 2121 and the second magnetic member 2122. The second magnetic member 2122 attracts a number of magnetic particles 241 to diffuse from the end of the first magnetic layer 211 close to the first magnetic member 2121 along the direction close to the second magnetic member 2122. Parameters may be arranged in advance in the control unit 7. The parameters are configured to adjust the magnitude of the first preset voltage. The first preset number of magnetic particles 241 may be uniformly diffused into the first distribution region in the magnetic layer 24 after a fixed period of time under the action of the second magnetic field.

In some embodiments, in response to the magnetic particles 241 diffusing into the first distribution region in the magnetic layer 24, the control unit 7 is configured to control the magnetic-field applying assembly 25 to apply a fifth magnetic field to the magnetic particles 241 and maintain a second preset duration, such that the magnetic particles 241 are enabled to remain stable in the magnetic layer 24. In this way, the magnetic particles 241 may remain stable for a certain period of time after being uniformly distributed in the first distribution region, such that the mobility of the carriers is enabled to remain stable, avoiding affecting display effect of the display panel 8 during the period of time. In some embodiments, magnetic field strength of the fifth magnetic field may be slightly smaller than or substantially equal to magnetic field strength of the second magnetic field.

In some embodiments, in response to the magnetic-field applying assembly 25 applying a fourth magnetic field to the magnetic particles 241 and maintaining the second preset duration, the control unit 7 is configured to control the magnetic-field applying assembly 25 to apply the first magnetic field to the magnetic particles 241, such that the magnetic particles 241 are enabled to move toward the end of the magnetic layer 24 (as shown in FIG. 2a). In this way, the sub-pixels 2 may restore brightness of the normal light emission after a short reduction in brightness, avoiding a affecting the display effect of the display panel 8. In some embodiments, the control unit 7 stops applying voltage to the second magnetic member 2122, and the magnetic particles 241 in the magnetic layer 24 are re-adsorbed by the first magnetic member 2121 and gathered at the end of the magnetic layer 24 close to the first magnetic member 2121. In this way, the carriers may be injected into the light-emitting layer 203 with normal mobility, and the sub-pixels 2 may emit light normally.

In some embodiments, in response to an energizing current of one of the sub-pixels 2 being greater than a threshold, the control unit 7 is configured to control a corresponding magnetic-field applying assembly 25 to apply a third magnetic field to the magnetic particles 241, such that a second preset number of magnetic particles 241 are enabled to diffuse from an end of the magnetic layer 24 to the other end of the magnetic layer 24 along the first direction X and into a second distribution region to reduce the recombination rate of holes and electrons. The first preset number may be substantially equal to the second preset number. The area of the first distribution region may be substantially equal to an area of the second distribution region. Because service life of the sub-pixels 2 may be easily affected by a relatively long duration or a relatively large energizing current at a same brightness, it is necessary to reduce the mobility of the carriers to reduce the recombination rate of holes and electrons. In some embodiments, the first preset number may be different from the second preset number, and the area of the first distribution region may be different from the area of the second distribution region, as long as the majority carriers are reduced to reduce the recombination rate.

In some embodiments, in response to the continuous luminous duration of one of the sub-pixels 2 being smaller than the first preset duration or the energizing current of one of the sub-pixels 2 being smaller than the threshold, the control unit 7 may be configured to control a corresponding magnetic-field applying assembly 25 to apply a sixth magnetic field to the magnetic particles 241. In this way, a fourth preset number of magnetic particles 241 may diffuse from an end of the magnetic layer 24 to the other end of the magnetic layer 24 along the first direction X and into a fourth distribution region, thereby reducing the quenching effect of the carriers on the exciton, and improving the light emission efficiency. Besides, the display panel 8 may be ensured to appropriately reduce the voltage applied to the sub-pixels 2 at a same brightness, thereby reducing the attenuation of the sub-pixels 2 and prolonging the service life. A magnetic field strength of the sixth magnetic field may be smaller than a magnetic field strength of the fifth magnetic field.

The present disclosure provides the control circuit 9 for controlling the display panel 8. The control circuit 9 includes the display driving unit 6 and the control unit 7. The display driving unit 6 is configured to drive the sub-pixels 2 of the display panel 8 to display an image. The control unit 7 is electrically connected to the display driving unit 6, and is configured to obtain the continuous luminous duration of each of the sub-pixels 2 of the display panel 8. The control unit 7 is also electrically connected to the magnetic-field applying assembly 25 of the each of the sub-pixels 2, and is configured to control the magnetic field strength of the magnetic-field applying assembly 25 in the corresponding one of the sub-pixels 2 based on the continuous luminous duration of the each of the sub-pixels 2, so as to adjust the distribution of the magnetic particles 241 in the magnetic layer 24 of the display panel 8. In this way, the magnetic particles 241 may diffuse in the magnetic layer 24 after the sub-pixels 2 continuously emit light for a long time, thereby greatly reducing the mobility of the majority carriers on the side of the light-emitting layer 203 toward the magnetic layer 24, and reducing the number of photons generated by recombination of electrons and holes. Besides, the luminous brightness of the sub-pixels 2 may be reduced, avoiding damage of the sub-pixels 2 caused by working at a same brightness for a long time and accelerating aging, and effectively extending the service life of the display panel 8.

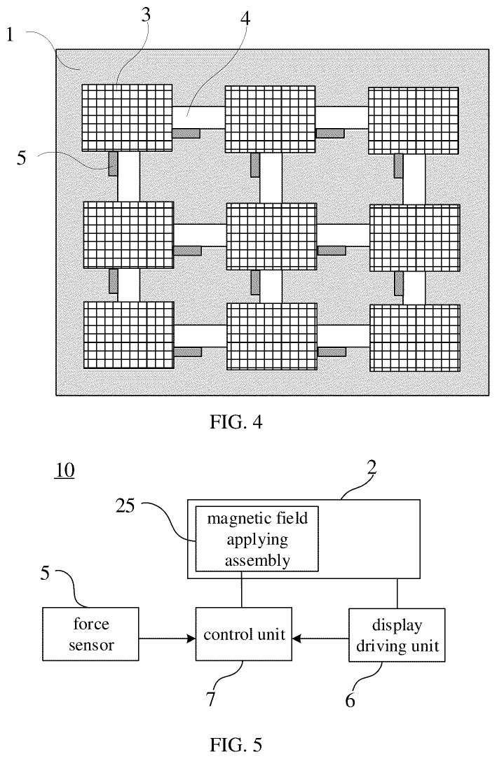

As shown in FIG. 4, FIG. 4 is a schematic structural view of a display panel based on a second embodiment of the present disclosure. The structure of the display panel 8 provided in the second embodiment of the present disclosure is basically the same as the structure of the display panel 8 provided in the first embodiment of the present disclosure, except that the display panel 8 provided in the second embodiment of the present disclosure is a stretchable display panel. The driving substrate 1 of the display panel 8 includes a flexible driving substrate. The driving substrate 1 may be a substrate with stretchable characteristics, which may be stretched and restored in a specific direction.

In some embodiments, the display panel 8 further includes a plurality of pixel islands 3 and a force sensor 5. The plurality of pixel islands 3 are arranged in an array on the driving substrate 1. Adjacent pixel islands 3 are arranged at intervals. Each of two adjacent pixel islands 3 is connected by a flexible connecting wire 4. The flexible connecting wire 4 between the pixel islands 3 is stretched synchronously with the flexible driving substrate. Each of the pixel islands 3 may include multiple sub-pixels 2 including the first sub-pixel 21, the second sub-pixel 22, and the third sub-pixel 23 with different colors. Each of the sub-pixels 2 includes the anode 201, the hole transport layer 202, the light-emitting layer 203, the electron transport layer 204, and the cathode 205.

The force sensor 5 is arranged on the flexible connecting wire 4, and is configured to test a tensile length or tensile strength of the flexible connecting wire 4. The tensile length of the flexible connecting wire 4 is a difference between a length of the flexible connecting wire 4 after tensile and a length of the flexible connecting wire 4 before tensile. The force sensor 5 may be a tension sensor 5 or a pressure sensor 5. In some embodiments, the force sensor 5 is the tension sensor. It can be understood that after the flexible connecting wire 4 is stretched and deformed, a tension of the flexible connecting wire 4 on the force sensor 5 may also be changed accordingly. There is a corresponding relationship between magnitude of the tension and the tensile length. The force sensor 5 may reflect the tensile length or tensile strength of the flexible connecting wire 4 based on the magnitude of the tension tested. That is, the magnitude of the tension of the force sensor 5 or a tensile length or tensile strength tested by the force sensor 5 may reflect a tensile degree of the display panel 8.

As shown in FIG. 5, FIG. 5 is a schematic view of a control circuit based on another embodiment of the present disclosure. The present disclosure provides a control circuit 10 for controlling the display panel 8 involved in the second embodiment mentioned above. In some embodiments, as shown in FIG. 1a, at least one of the plurality of sub-pixels 2 includes the magnetic layer 24 and the magnetic-field applying assembly 25. The magnetic layer 24 is arranged between the anode 201 and the hole transport layer 202 or between the cathode 205 and the electron transport layer 204. The magnetic layer 24 includes the plurality of magnetic particles 241. The magnetic-field applying assembly 25 includes the first magnetic member 2121 and the second magnetic member 2122 respectively arranged at two opposite ends of the magnetic layer 24 along the first direction X. At least one of the first magnetic member 2121 and the second magnetic member 2122 includes an electromagnet. The magnetic-field applying assembly 25 controls the distribution of the magnetic particles 241 of the magnetic layer 24 in the magnetic layer 24 based on test results of the force sensor 5.

In some embodiments, the control circuit 10 may also include a display driving unit 6 and a control unit 7. The display driving unit 6 is configured to drive the sub-pixels 2 of the display panel 8. The control unit 7 is electrically connected to the force sensor 5, and is configured to obtain the tensile length or tensile strength tested by the force sensor 5. The control unit 7 is also electrically connected to the magnetic-field applying assembly 25, and is configured to control the magnetic field strength of the magnetic-field applying assembly 25 based on the tensile length or tensile strength tested by the force sensor 5, so as to adjust the distribution of the magnetic particles 241 in the magnetic layer 24. In this way, the control unit 7 may control the distribution of the magnetic particles 241 in the magnetic layer 24 after the display panel 8 is stretched, thereby improving the luminous efficiency of the sub-pixels and the luminous brightness of the sub-pixels, avoiding uneven display before and after the display panel 8 is stretched, and effectively improving the user experience.

In some embodiments, in response to the tensile strength tested by the force sensor 5 being smaller than a preset value, the control unit 7 is configured to control the magnetic-field applying assembly 25 to apply the first magnetic field to the magnetic layer 24, such that the magnetic particles 241 are enabled to be distributed at an end of the magnetic layer 24 along the first direction X. In some embodiments, as shown in FIG. 2a, the control unit 7 may not apply voltage to the second magnetic member 2122. The magnetic particles 241 in the magnetic layer 24 are adsorbed by the first magnetic member 2121 and gathered at the end of the magnetic layer 24 close to the first magnetic member 2121. In this way, the carriers may be injected into the light-emitting layer 203 with normal mobility, and the sub-pixels emit light normally.

In response to the tensile strength tested by the force sensor 5 being greater than or substantially equal to the preset value, the control unit 7 is configured to control the magnetic-field applying assembly 25 to apply a fourth magnetic field to the magnetic layer 24, such that a third preset number of magnetic particles 241 are enabled to diffuse from an end of the magnetic layer 24 to the other end of the magnetic layer 24 along the first direction X and into a third distribution region, so as to reduce quenching effect of carriers on excitons. It should be noted that the third preset number may be smaller than the first preset number and the second preset number. An area of the third distribution region may be smaller than the area of the first distribution region and the area of the second distribution region. The brightness of the display panel 8 may be reduced when the display panel 8 is in a stretched state, thus a small amount of magnetic particles 241 is configured to slightly reduce the mobility of majority carriers to reduce the quenching of majority carriers on excitons, thereby ensuring that sufficient photons are generated and improving the brightness of the display panel 8.

In some embodiments, the control unit 7 is also configured to control the magnetic-field applying assembly 25 to apply a magnetic field with a corresponding magnetic field strength to the magnetic layer 24 based on the tensile strength tested by the force sensor 5. In some embodiments, different tensile strengths tested by the force sensor 5 may reflect different tensile degrees of the display panel 8. The control unit 7 may apply a corresponding voltage to the second magnetic member 2122 based on the tensile strength tested by the force sensor 5, such that the second magnetic member 2122 is enabled to be energized and forms magnetic fields with different magnetic field strengths with the first magnetic member 2121. In this way, the distribution of the magnetic particles 241 in the magnetic layer 24 may be determined based on different tensile degrees of the display panel 8, so as to accurately control the luminous efficiency of the sub-pixels, such that the display effect of the display panel 8 is enabled to remain stable under different tensile degrees.

In some embodiments, the sub-pixels 2 may include the first sub-pixel 21, the second sub-pixel 22, and the third sub-pixel 23 with different colors. Each of the pixel islands 3 is arranged with a plurality of first sub-pixels 21, a plurality of second sub-pixels 22, and a plurality of third sub-pixels 23. The control unit 7 is configured to control the luminous efficiency of all the sub-pixels on a corresponding one of the pixel islands 3 corresponding to the force sensor 5 based on a feedback signal of the force sensor 5. The color of the first sub-pixel 21 is blue. The magnetic-field applying assembly corresponding to the first sub-pixel 21 is the first magnetic-field applying assembly 212, and the magnetic layer 24 corresponding to the first sub-pixel 21 is the first magnetic layer 211. The first magnetic-field applying assembly 212 controls the distribution of the magnetic particles 241 of the first magnetic layer 211 in the first magnetic layer 211 based on the test results of the force sensor 5. The second sub-pixel 22 may include the second magnetic layer 221 and the second magnetic-field applying assembly 222. The third sub-pixel 23 may include the third magnetic layer 231 and the third magnetic-field applying assembly 232. For detailed descriptions of the second magnetic layer 221, the second magnetic-field applying assembly 222, the third magnetic layer 231, and the third magnetic-field applying assembly 232, reference may be made to the embodiments mentioned above.

Since the service life of the three color sub-pixels 2 are different, the brightness of the three color sub-pixels 2 may be increased to different degrees or selectively increased by using the magnetic particles 241 when the display panel 8 is in the stretched state. For example, the brightness of the second sub-pixel 22 or the brightness of the third sub-pixel 23 may be increased without increasing the brightness of the first sub-pixel 21, that is, the magnetic particles 241 in the first sub-pixel 21 may be gathered at an end of the first magnetic layer 211, and a small amount of magnetic particles 241 in the second sub-pixel 22 and a small amount of magnetic particles 241 in the third sub-pixel 23 are uniformly distributed in a corresponding magnetic layer 24. In this way, the mobility of the majority carriers may be slightly reduced, and the quenching effect of the majority carriers on the excitons may also be reduced, thereby improving the luminous efficiency.

The present disclosure provides the control circuit 10 including the display driving unit 6 and the control unit 7. The display driving unit 6 is configured to drive the sub-pixels 2 of the display panel 8. The control unit 7 is electrically connected to the force sensor 5 to obtain the tensile strength tested by the force sensor 5. The control unit 7 is also electrically connected to the magnetic-field applying assembly 25 to control the magnetic field strength of the magnetic-field applying assembly 25 based on the tensile strength tested by the force sensor 5, such that the distribution of the magnetic particles 241 in the magnetic layer 24 may be adjusted. In this way, after the display panel 8 is stretched, the distribution of the magnetic particles 241 in the magnetic layer 24 may be controlled by the control unit 7 to improve the luminous efficiency of the sub-pixels 2, thereby improving the luminous brightness of the sub-pixels 2, avoiding the uneven display of the display panel 8 before and after the display panel 8 is stretched, and effectively improving the user experience.

The above only describes the implementations of the present disclosure, and is not intended to limit the scope of protection of the present disclosure. Any equivalent structure or process alternations based on the specification of the present disclosure and the drawings, and their direct or indirect application in other related technical fields, are all similarly included in the scope of protection of the present disclosure.

What is claimed is:

1. A display panel, comprising:
a driving substrate; and
a plurality of sub-pixels, arranged on the driving substrate, wherein the sub-pixels comprise a first sub-pixel, a second sub-pixel, and a third sub-pixel with different colors, and each of the sub-pixels comprises an anode, a hole transport layer, a light-emitting layer, an electron transport layer, and a cathode, which are arranged in a stack on a side of the driving substrate;
at least one first sub-pixel comprises:
a first magnetic layer, arranged between the anode and the hole transport layer or between the cathode and the electron transport layer of the first magnetic layer, wherein the first magnetic layer comprises a plurality of magnetic particles; and
a first magnetic-field applying assembly, comprising a first magnetic member and a second magnetic member respectively arranged at two opposite ends of the first magnetic layer along a first direction, wherein at least one of the first magnetic member and the second magnetic member comprises an electromagnet, the first magnetic-field applying assembly is configured to control distribution of the magnetic particles in the first magnetic layer, and the first direction is perpendicular to a stacking direction of the display panel.

2. The display panel according to claim 1, wherein the first magnetic-field applying assembly is configured to be able to gather the plurality of magnetic particles at an end of the first magnetic layer, and further configured to be able to drive the plurality of magnetic particles to move toward the other end of the first magnetic layer, and when strength of a magnetic field applied to the first magnetic layer increases, the number of moving magnetic particles increases;
the first magnetic layer is defined with a plurality of accommodating grooves extending in the first direction, the plurality of accommodating grooves are arranged at intervals along a second direction, the magnetic particles are arranged in the accommodating grooves, and are able to move along the accommodating grooves under an action of the magnetic field, and the second direction is perpendicular to both the stacking direction of the display panel the first direction.

3. The display panel according to claim 2, wherein the first magnetic layer further comprises a base, a portion of a surface of the base away from the anode is in contact with the hole transport layer, and another portion of the surface of the base away from the anode is recessed to form the accommodating grooves.

4. The display panel according to claim 1, wherein the second sub-pixel comprises:
a second magnetic layer, arranged between the anode and the hole transport layer or between the cathode and the electron transport layer of the second sub-pixel, wherein the second magnetic layer comprises a plurality of magnetic particles; and
a second magnetic-field applying assembly, comprising a third magnetic member and a fourth magnetic member respectively arranged at two opposite ends of the second magnetic layer along the first direction, wherein at least one of the third magnetic member and the fourth magnetic member comprises an electromagnet, and the second magnetic-field applying assembly is configured to control distribution of the magnetic particles in the second magnetic layer.

5. The display panel according to claim 1, wherein the third sub-pixel comprises:
a third magnetic layer, arranged between the anode and the hole transport layer or between the cathode and the electron transport layer of the third sub-pixel, wherein the third magnetic layer comprises a plurality of magnetic particles; and
a third magnetic-field applying assembly, comprising a fifth magnetic member and a sixth magnetic member respectively arranged at two opposite ends of the third magnetic layer along the first direction, wherein at least one of the fifth magnetic member and the sixth magnetic member comprises an electromagnet, and the third magnetic-field applying assembly is configured to control distribution of the magnetic particles in the third magnetic layer.

6. The display panel according to claim 1, wherein color of the first sub-pixel is blue, color of the second sub-pixel is one of red and green, and color of the third sub-pixel is the other of red and green.

7. The display panel according to claim 1, wherein the driving substrate comprises a flexible driving substrate, and the display panel further comprises:
a plurality of pixel islands, arranged in an array on the driving substrate, wherein each of the plurality of pixel islands comprises a plurality of sub-pixels, and each of two adjacent pixel islands is connected by a flexible connecting wire; and
a force sensor, arranged on the flexible connecting wire, and configured to test a tensile length or tensile strength of the flexible connecting wire;
wherein, the first magnetic-field applying assembly is configured to control the distribution of the magnetic particles of the first magnetic layer in the first magnetic layer based on test results of the force sensor.

8. The display panel according to claim 1, wherein when one of the first magnetic member and the second magnetic member comprises the electromagnet magnet, the other one of the first magnetic member and the second magnetic member comprises a permanent.

9. A control circuit, configured to control a display panel, wherein the display panel comprises a plurality of sub-pixels, and at least one of the plurality of sub-pixels comprises:
an anode;
a hole transport layer;
a light-emitting layer;
an electron transport layer;
a cathode;
a magnetic layer, arranged between the anode and the hole transport layer or between the cathode and the electron transport layer, wherein the magnetic layer comprises a plurality of magnetic particles; and
a magnetic-field applying assembly, comprising a first magnetic member and a second magnetic member respectively arranged at two opposite ends of the magnetic layer along a first direction, wherein at least one of the first magnetic member and the second magnetic member comprises an electromagnet, the magnetic-field applying assembly is configured to control distribution of the magnetic particles in the magnetic layer, and the first direction is perpendicular to a stacking direction of the display panel;
wherein, the control circuit comprises:
a display driving unit, configured to drive the sub-pixels of the display panel to display an image; and
a control unit, electrically connected to the display driving unit and configured to obtain a continuous luminous duration of each of the sub-pixels of the display panel, wherein the control unit is further electrically connected to the magnetic-field applying assembly of the each of the sub-pixels, and configured to control magnetic field strength of the magnetic-field applying assembly based on the continuous luminous duration of the each of the sub-pixels, so as to adjust the distribution of the magnetic particles in the magnetic layer of the display panel.

10. The control circuit according to claim 9, wherein in response to the continuous luminous duration of one of the sub-pixels being smaller than a first preset duration, the control unit is configured to control a corresponding magnetic-field applying assembly to apply a first magnetic field to the magnetic particles, enabling the magnetic particles to be distributed at an end of the magnetic layer along the first direction; or
in response to the continuous luminous duration of one of the sub-pixels being greater than or substantially equal to the first preset duration, the control unit is configured to control a corresponding magnetic-field applying assembly to apply a second magnetic field to the magnetic particles, enabling a first preset number of magnetic particles to diffuse from an end of the magnetic layer to the other end of the magnetic layer along the first direction and into a first distribution region, so as to reduce a recombination rate of holes and electrons.

11. The control circuit according to claim 10, wherein in response to the magnetic particles diffusing into the first distribution region in the magnetic layer, the control unit is configured to control the magnetic field applying assembly to apply a fifth magnetic field to the magnetic particles and maintain a second preset duration.

12. The control circuit according to claim 9, wherein in response to an energizing current of one of the sub-pixels being greater than a threshold, the control unit is configured to control a corresponding magnetic-field applying assembly to apply a third magnetic field to the magnetic particles, enabling a second preset number of the magnetic particles to diffuse from an end of the magnetic layer to the other end of the magnetic layer along the first direction and into a second distribution region, so as to reduce a combination rate of holes and electrons.

13. The control circuit according to claim 9, wherein in response to the continuous luminous duration of one of the sub-pixels being smaller than a first preset duration or an energizing current of one of the sub-pixels being smaller than a threshold, the control unit is configured to control a corresponding magnetic field applying assembly to apply a sixth magnetic field to the magnetic particles, enabling a fourth preset number of magnetic particles to diffuse from an end of the magnetic layer to the other end of the magnetic layer along the first direction and into a fourth distribution region, so as to reduce quenching effect of carriers on exciton.

14. The control circuit according to claim 9, wherein the first magnetic-field applying assembly is configured to be able to gather the plurality of magnetic particles at an end of the first magnetic layer, and further configured to be able to drive the plurality of magnetic particles to move toward the other end of the first magnetic layer, and when strength of a magnetic field applied to the first magnetic layer increases, the number of moving magnetic particles increases;
the first magnetic layer is defined with a plurality of accommodating grooves extending in the first direction, the plurality of accommodating grooves are arranged at intervals along a second direction, the magnetic particles are arranged in the accommodating grooves, and are able to move along the accommodating grooves under an action of the magnetic field, and the second direction is perpendicular to both the stacking direction of the display panel the first direction.

15. The control circuit according to claim 14, wherein the first magnetic layer further comprises a base, a portion of a surface of the base away from the anode is in contact with the hole transport layer, and another portion of the surface of the base away from the anode is recessed to form the accommodating grooves.

16. A control circuit, configured to control a display panel, wherein the display panel comprises a plurality of sub-pixels, the plurality of sub-pixels form a plurality of pixel islands arranged in an array, each of two adjacent pixel islands is connected by a flexible connecting wire and a force sensor, and at least one of the plurality of sub-pixels comprises:
an anode;
a hole transport layer;
a light-emitting layer;
an electron transport layer;
a cathode;
a magnetic layer, arranged between the anode and the hole transport layer or between the cathode and the electron transport layer, wherein the magnetic layer comprises a plurality of magnetic particles; and
a magnetic-field applying assembly, comprising a first magnetic member and a second magnetic member respectively arranged at two opposite ends of the magnetic layer along a first direction, wherein at least one of the first magnetic member and the second magnetic member comprises an electromagnet, the magnetic-field applying assembly is configured to control distribution of the magnetic particles in the magnetic layer, and the first direction is perpendicular to a stacking direction of the display panel;
wherein the control circuit comprises:
a display driving unit, configured to drive the sub-pixels of the display panel; and
a control unit, electrically connected to the force sensor and configured to obtain a tensile length or tensile strength tested by the force sensor, and further electrically connected to the magnetic-field applying assembly and configured to control magnetic field strength of the magnetic-field applying assembly based on the tensile strength or tensile strength tested by the force sensor, so as to adjust the distribution of the magnetic particles in the magnetic layer.

17. The control circuit according to claim 16, wherein in response to the tensile strength tested by the force sensor being smaller than a preset value, the control unit is configured to control the magnetic-field applying assembly to apply a first magnetic field to the magnetic layer, enabling the magnetic particles to distributed at an end of the magnetic layer along the first direction; or
in response to the tensile strength tested by the force sensor being greater than or substantially equal to the preset value, the control unit is configured to control the magnetic-field applying assembly to apply a fourth magnetic field to the magnetic layer, enabling a third preset number of magnetic particles to diffuse from an end of the magnetic layer to the other end of the magnetic layer along the first direction and into a third distribution region, so as to reduce quenching effect of carriers on excitons.

18. The control circuit according to claim 16, wherein the sub-pixels comprises a first sub-pixel, a second sub-pixel, and the third sub-pixel of different colors, each of the pixel islands is arranged with a plurality of first sub-pixels, a plurality of second sub-pixels, and a plurality of third sub-pixels.

19. The control circuit according to claim 16, wherein the first magnetic-field applying assembly is configured to be able to gather the plurality of magnetic particles at an end of the first magnetic layer, and further configured to be able to drive the plurality of magnetic particles to move toward the other end of the first magnetic layer, and when strength of a magnetic field applied to the first magnetic layer increases, the number of moving magnetic particles increases;
the first magnetic layer is defined with a plurality of accommodating grooves extending in the first direction, the plurality of accommodating grooves are arranged at intervals along a second direction, the magnetic particles are arranged in the accommodating grooves, and are able to move along the accommodating grooves under an action of the magnetic field, and the second direction is perpendicular to both the stacking direction of the display panel the first direction.

20. The control circuit according to claim 19, wherein the first magnetic layer further comprises a base, a portion of a surface of the base away from the anode is in contact with the hole transport layer, and another portion of the surface of the base away from the anode is recessed to form the accommodating grooves.
